(19) United States
(12) Patent Application Publication
(10) Pub. No.: US 2007/0140009 A1
(43) Pub. Date: Jun. 21, 2007

(54) Virtual ground type nonvolatile semiconductor memory device

(75) Inventor: Nobuhiko Ito, Tenri-shi (JP)

Correspondence Address: MORRISON & FOERSTER LLP, 755 PAGE MILL RD, PALO ALTO, CA, 94304-1018, US

(73) Assignee: SHARP KABUSHIKI KAISHA, Osaka-shi (JP)

(21) Appl. No.: 11/635,122

(22) Filed: Dec. 6, 2006

(30) Foreign Application Priority Data
Dec. 7, 2005 (JP) 2005-353411

(51) Int. Cl. G11C 16/04; G11C 16/06; G11C 11/34

(52) U.S. Cl. 365/185.16; 365/185.03; 365/185.2

(57) ABSTRACT

A nonvolatile semiconductor memory device comprises a ground voltage applying circuit for applying a ground voltage to a selected source line connected to a source of a selected memory cell, a reading circuit for supplying a reading current to the selected memory cell via a selected bit line and detecting data of the selected memory cell, a bit line selection circuit for selecting the selected bit line and connecting it to the reading circuit. The bit line selection circuit can select an additional bit line group located at the opposite side of the selected source line with respect to the selected bit line and connect it to the reading circuit and a current path from the reading circuit branches into current paths to the selected bit line and respective bit lines of the additional bit line group at the side of the reading circuit from the bit line selection circuit.

### CROSS REFERENCE TO RELATED APPLICATION

This Nonprovisional application claims priority under 35 U.S.C. §119(a) on Patent Application No. 2005-353411 filed in Japan on 7 Dec., 2005, the entire contents of which are hereby incorporated by reference.

### BACKGROUND OF THE INVENTION

1. Field of the Invention

The present invention relates to a nonvolatile semiconductor memory device and particularly to a data reading circuit of a nonvolatile semiconductor memory device with a virtual ground type memory cell array.

2. Description of the Related Art

In recent years, along with a higher performance of a cellular telephone and increase in use of markets such as a memory card and a file, a flash memory having a large volume, which is one of nonvolatile semiconductor memory devices, has been increased. In order to reduce a cost thereof, a device with a small effective memory cell area using multilevel storage and a memory cell array of a virtual ground type has been continuously developed. Particularly, the memory cell area of the memory cell array of the virtual ground type can be reduced by devising a circuit, so that a device with a small chip area can be developed in the same manufacturing process as the conventional one.

However, since this memory cell array of the virtual ground type has a virtual ground structure such that a source region or a drain region in one of two adjacent memory cells in a row direction and a source region or a drain region in the other of the two memory cells are connected with each other, a leak current (hereinafter, arbitrarily referred to as “an adjacent memory cell leak current”) cannot be ignored, which flows from a memory cell as a reading object (hereinafter, arbitrarily referred to as “a selected memory cell”) to a memory cell adjacent to the selected memory cell (hereinafter, arbitrarily referred to as “an adjacent memory cell”) or flows from the adjacent memory cell into the selected memory cell. Therefore, various devices are necessary in order to realize reading at a high speed.

In order to improve the above-described problem, the following Japanese Unexamined Patent Publication No. 7-73684 (hereinafter, referred to as a publicly-known document 1) and Japanese Unexamined Patent Publication No. 9-198889 (hereinafter, referred to as a publicly-known document 2) respectively suggest a reading method of a memory cell array of a virtual ground type.

FIG. 3 and FIG. 4 illustrate the configuration of the memory cell array of the virtual ground type, and a current path and a bias condition upon reading operation, as disclosed in the publicly-known document 1. The reading operation shown in FIG. 3 and FIG. 4 will be described below. FIG. 3 shows a case of reading a memory cell Qₘ₂ of an array segment SEGᵢ, and FIG. 4 shows a case of reading a memory cell Qₘ₃ of the array segment SEGᵢ, respectively.

As shown in FIG. 3, in a case of reading the memory cell Qₘ₂ of the array segment SEGᵢ, a word line WLᵢ₁ connected to a control gate of the selected memory cell Qₘ₂ is supplied with a voltage of 5V and the other word lines are supplied with a voltage of 0V. The selection of a memory cell in a row direction is carried out by a row selection decoder provided for each array segment (not illustrated). In addition, a selection line SELᵢ₀ of the array segment SEGᵢ is supplied with a voltage of 5V, and a selection line SELᵢ₁ of the array segment SEGᵢ and selection lines of the other array segments are supplied with a voltage of 0V. Thereby, the array segment SEGᵢ including the selected memory cell Qₘ₂ is selected, and connections to main bit lines MBL provided one by one to two sub bit lines SBL are changed. This selection and change are carried out by a decoder to decode one bit of an address for selecting an array segment and a column address (not illustrated) in a composite manner. Further, one main bit line MBL₁ out of two selected main bit lines electrically connected to the selected memory cell Qₘ₂ is supplied with a voltage of 0V, and the other main bit line MBL₂ is supplied with a voltage of 1V. In this case, a voltage of an unselected main bit line, which is not electrically connected to the selected memory cell Qₘ₂, is made the same as the voltage of the adjacent selected main bit line or is made into an open condition. For example, the voltage of the main bit line (not illustrated) at the left side of the selected main bit line MBL₁ is made the same as the voltage 0V of the selected main bit line MBL₁ or is made into the open condition, and the voltages of the main bit lines MBL₃, MBL₄, . . . at the right side of the selected main bit line MBL₂ are made the same as the voltage 1V of the selected main bit line MBL₂ or is made into the open condition. This selective application of a voltage to main bit lines is carried out by a column selection decoder (not illustrated). Thereby, the same potential is supplied or the open condition is provided between a source and a drain of an unselected memory cell (hereinafter, conventionally, referred to as “a semi-selected memory cell”), which is selected in the same row as the selected memory cell Qₘ₂ in a row direction but is not selected in a column direction, so that it is possible to prevent an adjacent memory cell leak current due to the semi-selected memory. As a result, it is possible to read information from the memory cell Qₘ₂ depending on presence or absence of the current in this current path because only the current paths of the main bit line MBL₂, a selection transistor Q_{S3}, a sub bit line SBLᵢ₃, the memory cell Qₘ₂, a sub bit line SBLᵢ₂, a selection transistor Q_{S2}, and the main bit line MBL₁ exist. In other words, if an electron is injected to a floating gate of the memory cell Qₘ₂ and a threshold voltage thereof is not less than 5V, for example (a writing state), a reading current does not flow through the current path, and on the contrary, if no electron is injected to the floating gate of the memory cell Qₘ₂ and the memory cell Qₘ₂ is in an erasing state, the threshold voltage is made less than 5V and the reading current flows. Such presence or absence of the reading current is detected by a sense amplifier (not illustrated). Further, in FIG. 3, the voltage of a substrate bias line V_{BB} is 0V.

In addition, as shown in FIG. 4, in a case of reading a memory cell Qₘ₃ of the array segment SEGᵢ, a word line WLᵢ₁ connected to the control gate of the memory cell Qₘ₃ is supplied with a voltage of 5V and the other word lines are supplied with a voltage of 0V. Further, a selection line SELᵢ₁ of the array segment SEGᵢ is supplied with a voltage of 5V, and a selection line SELᵢ₀ of the array segment SEGᵢ and selection lines of the other array segments are supplied with a voltage of 0V. Further, the main bit line MBL₁ is supplied with a voltage of 0V, and the main bit line MBL₂ is supplied with a voltage of 1V. Also in this case, the voltage of the unselected main bit line is the same as the voltage of the adjacent selected main bit line or is made into the open state. Thereby, the same potential is provided or the open state is provided between the source and the drain of the semi-selected memory cell, so that it is possible to prevent the adjacent memory cell leak current due to the semi-selected memory cell. As a result, it is possible to read the information from the selected memory cell Qₘ₃ depending on presence or absence of the current in this current path because only the current paths of the main bit line MBL₂, the selection transistor Q_{S3}, a sub bit line SBLᵢ₄, the memory cell Qₘ₃, a sub bit line SBLᵢ₃, the selection transistor Q_{S2}, and the main bit line MBL₁ exist. In FIG. 4, the voltage of the substrate bias line V_{BB} is 0V.

In addition, FIG. 5 and FIG. 6 illustrate a circuit constitutional example for causing short circuit between the adjacent bit lines in the memory cell array of the virtual ground type, which is disclosed in the publicly-known document 2. The reading operation in the memory cell array of the virtual ground type show in FIG. 5 and FIG. 6 will be described.

In FIG. 5, a memory cell array of a virtual ground type having memory transistors 1 arranged in a matrix are illustrated. Each of sources and drains of these memory transistors is connected to a bit line BL. The memory transistors in the same row are connected at their gates to a word line WL. The bit line BL is shared between two memory transistors adjacent in a row direction with the exception of each column at the both outer sides. Control transistors 2 are provided between the adjacent two bit lines, respectively, so as to be capable of causing a short circuit via a bit line between a source and a drain of a memory transistor which is connected to the activated word line but not a reading object. Then, the source and the drain of each control transistor 2 are connected to each bit line, respectively, and the gate of each control transistor 2 is connected to the corresponding control line ST. On and off of each control transistor 2 is controlled via these control lines ST. Due to this circuit constitution, all control transistors can be conducted except the control transistor which is arranged in the same row as the memory cell as the reading object. Short circuit is caused in the bit line connected to the control transistor in a conductive state via the control transistor. If all memory cells are activated, which are arranged in the same row as the memory cell as the reading object via the word line, a reading voltage is applied between the furthest outer both bit lines. Thereby, it is directly examined if the memory cell as the reading object is conducted or not. Further, the memory cell array shown in FIG. 5 briefly shows a part of the memory cell arrays of the virtual ground type.

FIG. 6 shows another circuit constitutional example of the control transistor 2 shown in FIG. 5. The arrangement of the control transistor 2 in the circuit constitutional example shown in FIG. 6 is equivalent to the arrangement of a binary decoder. In the arrangement of the control transistor 2 of each row, there are complementary plural pairs of rows and in any one row of each pair, the control transistor 2 is always located. In addition, in the first pair, the arrangement of the control transistor 2 is exchanged for each column; in the second pair, the arrangement of the control transistor 2 is exchanged for each two columns; in the third pair, the arrangement of the control transistor 2 is exchanged for each four columns; and in the n-th pair, the arrangement of the control transistor 2 is exchanged for each 2ⁿ columns. According to the example shown in FIG. 6, there are provided three pairs of the complementary rows (namely, six rows), and inner address signals of A0 and A0#, A1 and A1#, and A2 and A2#, which are complementary pairs each other, are supplied to each row as a gate signal of the control transistor 2. A mark # represents that a signal is reversed from the former signal in signal level. For example, if the memory cell located between the third bit line and the fourth bit line from left in FIG. 6 is the reading object, by making the level of each of the inner address signals A0, A1#, and A2 to be inputted in each gate of three control transistors 2 located between the third bit line and the fourth bit line have signal levels into a signal level (a low level) making these control transistors into a no-conductive state and on the contrary, making the level of each of the inner address signals A0#, A1, and A2# to be inputted in each gate of three control transistors 2 into a signal level (a high level) making these control transistors into a conductive state, at least one of the control transistors arranged between respective bit lines other than between the third bit line and the fourth bit line is made into a conductive state so as to cause short circuit between these bit lines.

However, a data reading system for a conventional memory cell array of a virtual ground type disclosed in the publicly-known documents 1 and 2 involves a following problem.

FIG. 7 shows a typical example of the reading circuit constitution shown in the publicly-known document 1. In this case, reference marks WL1, WL2 denote word lines; the reference mark SEL denotes a block selection signal to be inputted in a gate of a block selection transistor; the reference mark Icell denotes a reading current of the selected memory; the reference mark Ileak denotes a leak current from a memory cell which is virtual-ground-connected; the reference mark R1 denotes a synthetic resistance of a wire resistance of a main bit line and an on-resistance of a column selection transistor for selecting the main bit line; and the reference mark R2 denotes the wire resistance of a sub bit line. When carrying out the reading operation of a selected memory cell Q₂₁, a voltage of a drain (an (A) point in the drawing) of the selected memory cell Q₂₁ causes a voltage drop from an input end (a (D) point in the drawing) of a reading circuit due to the resistances R1 and R2 and the reading current Icell. In the same way, the voltage of a branch point (an (F) point in the drawing) branched to two sub bit lines from the main bit line via the block selection transistor also causes a voltage drop from the (D) point due to the resistance R1 and the reading current Icell. On the other hand, a sub bit line (a (C) point in the drawing) having a voltage supplied thereto from the adjacent main bit line (an (E) point in the drawing) has the same voltage as the (E) point, so that there is a voltage difference between the (F) point and the (C) point. When an memory cell Q₂₃ adjacent at the drain side of the selected memory cell Q₂₁ across one memory cell is erased and its threshold voltage is low, the memory cell Q₂₃ is conducted so as to cause the leak current Ileak. Accordingly, a reading current Iread to be supplied to the selected memory cell Q₂₁ which is observed at the side of a sense amplifier SA is represented by the following mathematical expression 1.
Iread=Icell−Ileak (Mathematical Expression 1)

In this case, the leak current Ileak is changed depending on the threshold voltage of the memory cell Q₂₃, and this results in that the reading current Iread to be observed at the side of the sense amplifier SA is changed depending on the influence of the threshold voltages of the other memory cells which are virtual-ground-connected. In other words, even if the threshold value of an arbitrary memory cell is set at a predetermined value, when the threshold values of the peripheral memory cells are changed due to writing of the data after that, the reading current of the memory cell of which the threshold value has been set at first is changed so as to deteriorate a reading margin.

In addition, according to the data reading system of the memory cell array of the virtual ground type disclosed in the publicly-known document 2, in the all columns except the same column as the selected memory cell, a control transistor for causing short circuit between the adjacent bit lines is provided, so that no leak current to be generated in the data reading system disclosed in the publicly-known document 1 is generated; however, there is necessary to prepare many control transistors for causing short circuit between the adjacent bit lines. Therefore, this involves a problem such that the circuit constitution around the memory cell array is complicated and the size of the chip is increased. In addition, because of the configuration to cause short circuit in each of the all bit lines located at the drain side of the selected memory cell, there is a disadvantage such that the capacity of the bit line to be connected to the sense amplifier is made larger and the reading time is made longer.

### SUMMARY OF THE INVENTION

The present invention has been made taking the foregoing problems into consideration and an object of which is to provide a nonvolatile semiconductor memory device of a virtual ground type to enable to read the data from a memory cell array of a virtual ground type at a high speed and with a high degree of accuracy without being given an influence of a leak current changing in accordance with a threshold voltage of other memory cells to be connected to the same word line as a memory cell as a reading object.

In order to attain the above-described object, according to the first aspect of the present invention, there is provided a virtual ground type nonvolatile semiconductor memory device including a virtual ground type memory cell array consisting of a plurality of memory cells, each having a MOSFET construction, arranged in a matrix in a row direction and a column direction, wherein gates of the memory cells in the same row are connected to a common word line extending in the row direction; drain regions and source regions of the memory cells in the same column are separately connected to two bit lines, each extending in the column direction; and a drain region or a source region of one of the two memory cells adjacent in the row direction and a drain region or a source region of the other of the two memory cells are connected with each other to share the bit line. This nonvolatile semiconductor memory device of the virtual ground type comprises a ground voltage applying circuit for applying a ground voltage to a selected source line which is the bit line connected to a source region of a selected memory cell to be read of the memory cells during a reading operation; a reading circuit for supplying a reading current to the selected memory cell via a selected bit line which is the bit line connected to the drain region of the selected memory cell during a reading operation and detecting stored data of the selected memory cell based on the reading current; and a bit line selection circuit for selecting the selected bit line from the bit lines and connecting the selected bit line to the reading circuit. The bit line selection circuit can select an additional bit line group made of one or more arbitrary bit lines located at an opposite side of the selected source line with respect to the selected bit line from the bit lines, and connect the additional bit line group to the reading circuit. Further, a current path from the input end of the reading circuit branches into current paths to the selected bit line and respective bit lines of the additional bit line group at the side of the reading circuit from the bit line selection circuit.

According to the second aspect of the present invention, in the nonvolatile semiconductor memory device of the virtual ground type of the first aspect of the present invention, the bit line selection circuit makes adjacent bit lines which are one or more arbitrary bit lines located at an opposite side of the selected source line with respect to the selected bit line to be unselected and into a floating state.

According to the third aspect of the present invention, in the nonvolatile semiconductor memory device of the virtual ground type of the second aspect of the present invention, the adjacent bit line to be made into the floating state by the bit line selection circuit is charged to a predetermined pre-charged voltage before being made into the floating state.

According to the fourth aspect of the present invention, in the nonvolatile semiconductor memory device of the virtual ground type of the third aspect of the present invention, the adjacent bit line to be made into the floating state by the bit line selection circuit is charged to a pre-charged voltage which is the same as the voltage of the selected bit line before being made into the floating state.

According to the fifth aspect of the present invention, in the nonvolatile semiconductor memory device of the virtual ground type of any one of the above-described aspects of the present invention, in a case where another bit line exists at the outside from the additional bit line group as seen from the selected bit line, the bit line selection circuit makes an outside bit line located at the outside to be unselected and into a floating state.

According to the sixth aspect of the present invention, in the nonvolatile semiconductor memory device of the virtual ground type of the fifth aspect of the present invention, the outside bit line to be made into the floating state by the bit line selection circuit is charged to a predetermined pre-charged voltage before being made into the floating state.

According to the seventh aspect of the present invention, in the nonvolatile semiconductor memory device of the virtual ground type of the sixth aspect of the present invention, the outside bit line to be made into the floating state by the bit line selection circuit is charged to a pre-charged voltage, which is the same as the voltage of the selected bit line before being made into the floating state.

According to the eighth aspect of the present invention, in the nonvolatile semiconductor memory device of the virtual ground type of the first to fourth aspects of the present invention, in a case where another bit line exists at the outside from the additional bit line group as seen from the selected bit line, a predetermined bias voltage is applied to an outside bit line located at the outside.

According to the ninth aspect of the present invention, in the nonvolatile semiconductor memory device of the virtual ground type of the eighth aspect of the present invention, the bias voltage to be applied to the outside bit line is the same as the voltage of the selected bit line.

According to the tenth aspect of the present invention, in the nonvolatile semiconductor memory device of the virtual ground type of any aspect of the above-described aspects of the present invention, the reading circuit may include a current-voltage converting circuit for converting a change in the reading current flowing through the selected memory cell via the selected bit line into a change in voltage and outputting the change in voltage as a reading voltage while suppressing a voltage variation on the selected bit line and a sense amplifier for amplifying the reading voltage to be outputted from the current-voltage converting circuit.

According to the eleventh aspect of the present invention, in the nonvolatile semiconductor memory device of the virtual ground type of any aspect of the above-described aspects of the present invention, the memory cell array is divided into a plurality of blocks in a column direction; the bit line extending in the column direction is divided in blocks; each bit line in the block is connected to a main bit line corresponding to the bit line one-on-one via a block selection transistor; the block including the selected memory cell is selected by the block selection transistor; and the bit line selection circuit selects the main bit line to be connected independently to the selected bit line and each bit line of the additional bit line group via the block selection transistor when selecting the selected bit line and the additional bit line group from the bit lines.

In the nonvolatile semiconductor memory device of the virtual ground type of the eleventh aspect of the present invention, a source electrode of the block selection transistor which is provided on each bit line for each block is independently connected to any one side of the both ends of each bit line; the connecting positions of the block selection transistors are different between odd-numbered bit lines and even-numbered bit lines; and the block selection transistor to be connected to the odd-numbered bit line and the block selection transistor to be connected to the even-numbered bit line are independently controlled to be turned on and off.

According to the nonvolatile semiconductor memory device of the virtual ground type of the present invention, since the same voltages are supplied to the selected bit line and the additional bit line group from the input end of the reading circuit, it is possible to prevent the leak current flowing through another adjacent memory cell connected to the same word line as the memory cell to be read located between the both bit lines. In addition, since a current path from the input end of the reading circuit branches into current paths to the selected bit line and respective bit lines of the additional bit line group at the side of the reading circuit from the bit line selection circuit, the circuit for selecting the bit line is not necessary at the side of the reading circuit from this branching point. Therefore, there is no synthetic resistance of the on-resistance of the transistor configuring this circuit and the wire resistance for constructing this circuit, so that it is possible to keep a voltage drop due to a parasitic resistance and a reading current from the input end of the reading circuit to this branching point to nearly zero, and further, it is also possible to prevent a leak current caused by this voltage drop when the same voltage as the voltage at the input end of the reading circuit is applied to the bit line other than the selected bit line and the additional bit line group. As a result of these aspects, upon the data reading for the memory cell array of the virtual ground type, it is possible to transfer the reading current flowing through the selected memory cell with a high efficiency to the side of the sense amplifier without being influenced by the leak current changing in accordance with the threshold voltage of other memory cells connected to the same word line as the memory cell to be read, so that the reading operation at a high speed and a high degree of accuracy can be realized.

### BRIEF DESCRIPTION OF THE DRAWINGS

FIG. 1 is a circuit diagram showing a substantial part circuit constitutional example according to an embodiment of a nonvolatile semiconductor memory device of a virtual ground type of the present invention;

FIG. 2 is a circuit diagram showing a substantial part circuit constitutional example according to other embodiment of a nonvolatile semiconductor memory device of a virtual ground type of the present invention;

FIG. 3 is a circuit diagram showing an example of the constitution of a conventional memory cell array of a virtual ground type, and a current path and a bias condition when carrying out the reading operation;

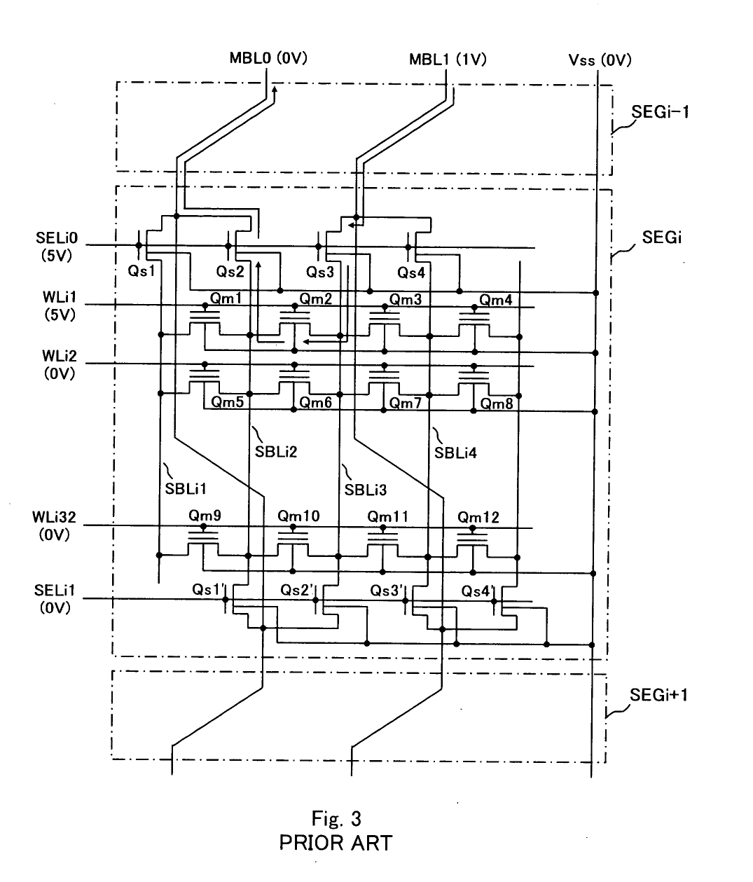

FIG. 4 is a circuit diagram showing another example of the constitution of the conventional memory cell array of the virtual ground type, and the current path and the bias condition when carrying out the reading operation;

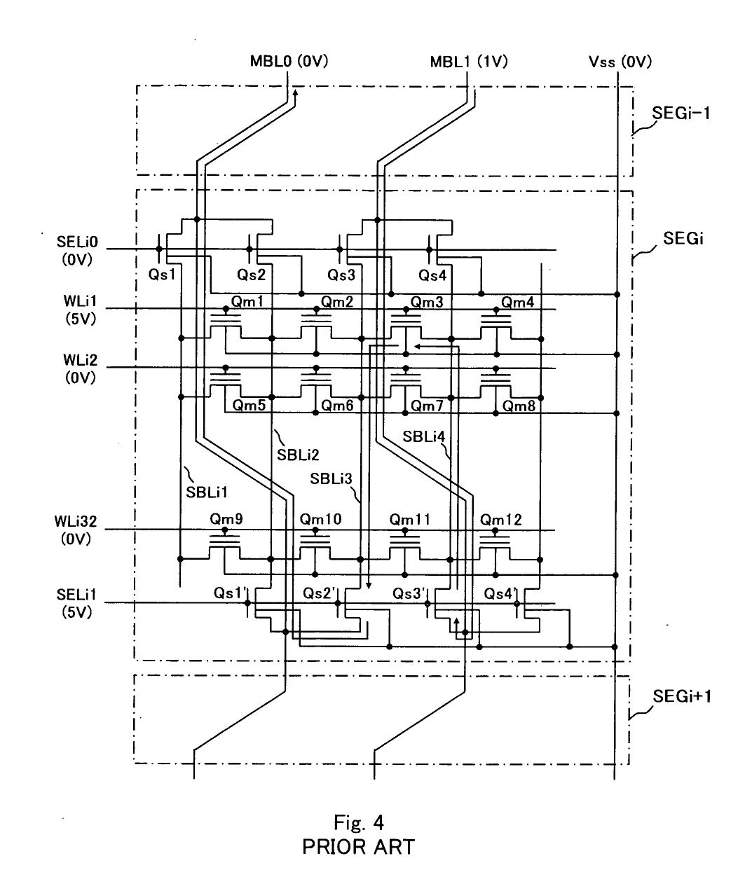

FIG. 5 is a circuit diagram showing a circuit constitutional example for causing short circuit between adjacent bit lines in the conventional memory cell array of the virtual ground type;

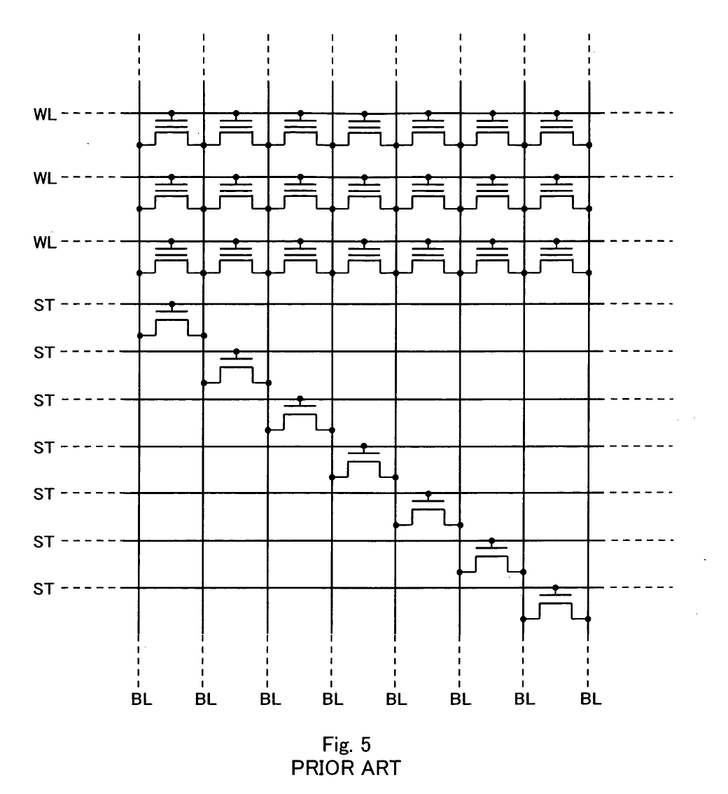

FIG. 6 is a circuit diagram showing another circuit constitutional example for causing short circuit between adjacent bit lines in the conventional memory cell array of the virtual ground type; and

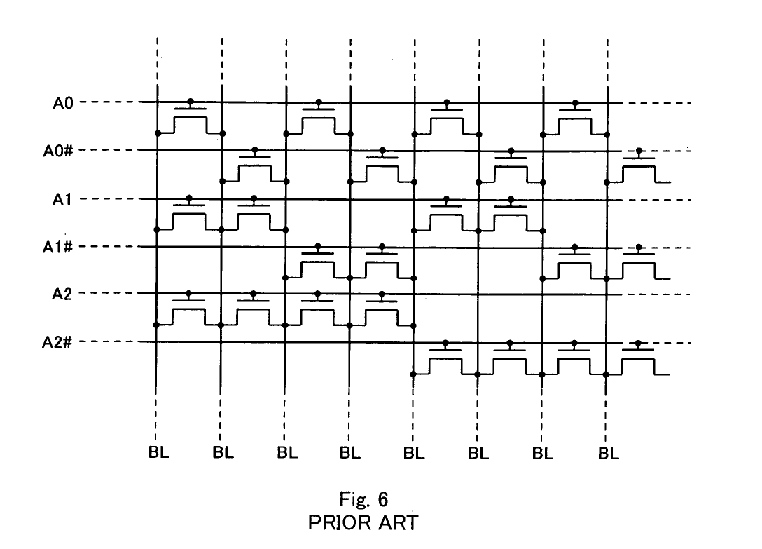

FIG. 7 is a circuit diagram showing a typical example of a reading circuit constitution of the conventional memory cell array of the virtual ground type shown in FIG. 3 and FIG. 4.

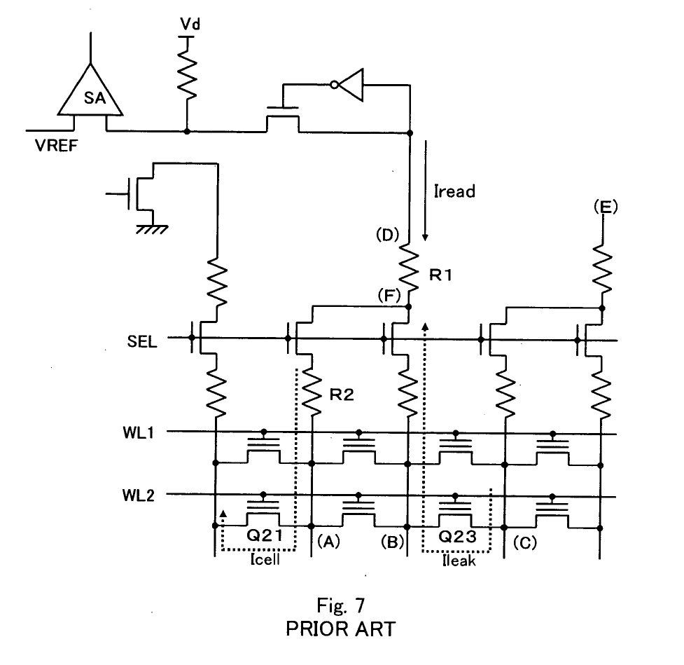

### DETAILED DESCRIPTION OF THE INVENTION

Embodiments of a nonvolatile semiconductor memory device of a virtual ground type according to the present invention (hereinafter, arbitrarily referred to as “the device according to the present invention”) will be described below with reference to the drawings.

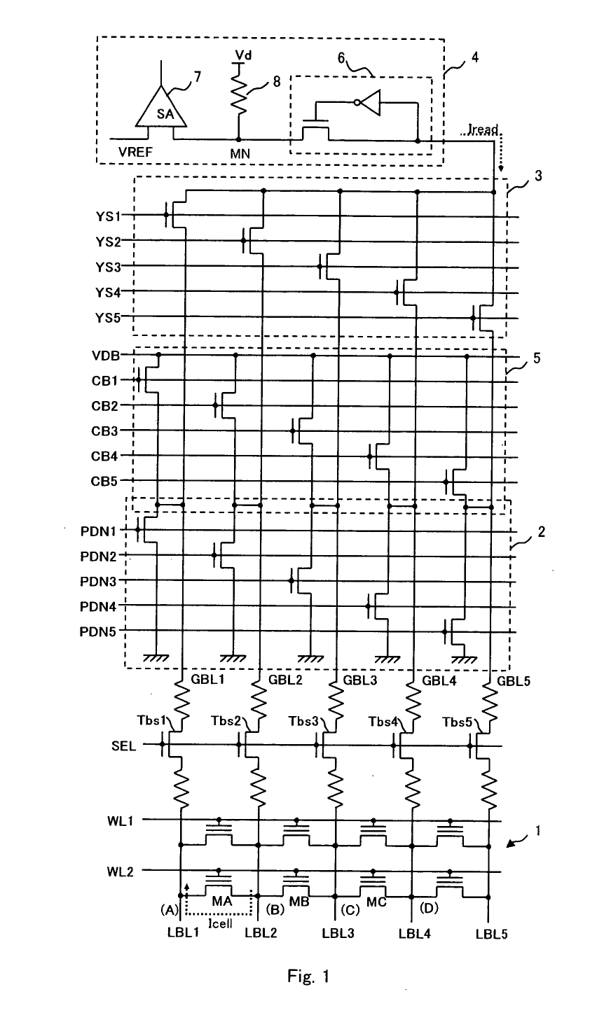

FIG. 1 is a circuit diagram showing an example of a circuit constitution of the device according to the present invention. As shown in FIG. 1, the device according to the present invention is configured being provided with at least a memory cell array 1, a ground voltage applying circuit 2, a bit line selection circuit 3, a reading circuit 4, and a drain voltage applying circuit 5. Further, FIG. 1 only shows substantial parts necessary for description of a characteristic part of the device according to the present invention, and the descriptions of an address input circuit, an address decoder circuit, an output buffer circuit, a control circuit for writing and erasing, and a voltage generating circuit or the like provided in a general nonvolatile semiconductor memory device of a virtual ground type are omitted.

The memory cell array 1 is a memory cell array of a virtual ground type, which is configured in such a manner that a plurality of memory cell of a MOSFET construction is aligned in a matrix in a row and column directions; a control gate of a memory cell in the same row is connected to common word lines WL1 and WL2 extending in a row direction; drain regions and source regions of memory cells in the same row are separately connected to two of local bit lines LBL1 to 5 (equivalent to bit lines) extending in a column direction, and a drain region or a source region of one of two memory cells adjacent in a row direction and a drain region or a source region of the other of the two memory cells are connected with each other to share one bit line. The memory cell according to the present embodiment is a flash memory cell of a stuck type having a float gate, an insulating film, and a control gate laminated on a channel region via a tunnel insulating film.

In addition, in FIG. 1, as the memory cell array 1, only one part (2 rows×4 columns) of the entire memory cell array is illustrated for ease of explanation; however, in practice, the memory cell array 1 is divided into a plurality of blocks in a column direction (the extending direction of the local bit lines LBL1 to 5) and each block is alternatively selected by a block selection signal SEL. According to the example shown in FIG. 1, the local bit lines LBL1 to 5 of each block are separately connected to global bit lines GBL1 to 5 (equivalent to main bit lines) via block selection transistors Tbs1 to 5 having a block selection signal SEL as a gate signal. Respective global bit lines GBL1 to 5 are connected to the reading circuit 4 via the bit line selection circuit 3, respectively. In addition, the global bit lines GBL1 to 5 are also connected to the ground voltage applying circuit 2 and the drain voltage applying circuit 5.

The ground voltage applying circuit 2 is a circuit to selectively connect the local bit lines LBL1 to 5 of the selected block to ground via the global bit lines GBL1 to 5, and when carrying out the reading operation, the ground voltage applying circuit 2 selects the bit line to be connected to the source region of the selected memory cell to be read as a selected source line so as to apply a ground voltage to this bit line. Selection of the local bit lines LBL1 to 5 to be connected to ground is carried out by selectively conducting a N channel MOSFET in which respective gates are separately connected to ground control signals PDN 1 to 5, respective drains are separately connected to global bit lines GBL1 to 5, and respective sources are separately connected to ground voltages by means of the ground control signals PDN 1 to 5 corresponding to the local bit lines LBL1 to 5, respectively.

Selecting a selected bit line connected to the drain region of the selected memory cell and an additional bit line group made of one or more arbitrary local bit lines located at the opposite side of the selected source line with respect to the selected bit line from the local bit lines LBL1 to 5 during the reading operation, the bit line selection circuit 3 connects the selected bit line and the additional bit line group to the reading circuit 4. Selection of the local bit lines LBL1 to 5 to be connected to the reading circuit 4 is carried out by selectively conducting the N channel MOSFET in which respective gates are separately connected to bit line selection signals YS1 to 5, respective sources are separately connected to global bit lines GBL1 to 5, and respective drains are separately connected to an input end CMN of the reading circuit 4 by means of the bit line selection signals YS1 to 5 corresponding to the local bit lines LBL1 to 5, respectively.

The reading circuit 4 is a circuit to supply a reading current to a selected memory cell via the selected bit line which is selected in the bit line selection circuit 3 during the reading operation and detect the memory data of the selected memory cell based on this reading current. According to the present embodiment, the reading circuit 4 is configured being provided with a current-voltage converting circuit 6 to convert a change in the reading current flowing through the selected memory cell via the selected bit line into a voltage change while controlling the voltage variation of the selected bit line and output this voltage change as a reading voltage V_{READ}; a sense amplifier 7 to amplify the reading voltage V_{READ} to be outputted from the current-voltage converting circuit 6; and a load circuit 8 connected to an output end MN of the current-voltage converting circuit 6 to supply the reading current to the side of the memory cell array 1 via the current-voltage converting circuit 6.

More specifically, the current-voltage converting circuit 6 is configured being provided with the N channel MOSFET put between the input end CMN and the output end MN, and an inverter having the output connected to the gate of this MOSFET and the input connected to the input end CMN. In addition, the sense amplifier 7 is configured by a differential amplifier having the reading voltage V_{READ} and a reference voltage V_{REF} as a differential input. The load circuit 8 is represented by a load resistance put between a power wire Vd and the output terminal MN for simplification in FIG. 1; however, the load circuit 8 may be configured by a P channel MOSFET or the like other than the load resistance.

The drain voltage applying circuit 5 serves as a circuit to select a writing object bit line connected to the drain region of the memory cell of the writing object from the local bit lines LBL1 to 5 and apply the writing drain voltage to be supplied from a drain voltage supply wire VDB to the selected writing object bit line via the corresponding global bit lines GBL1 to 5. Selection of the writing object bit line is carried out by selectively conducting the N channel MOSFET in which the gates are separately connected to drain voltage control signals CB1 to 5, the sources are separately connected to the global bit lines GBL1 to 5, and the drains are separately connected to the drain voltage supply lines VDB, by means of the drain voltage control signals CB1 to 5 corresponding to the local bit lines LBL1 to 5, respectively.

In addition, the drain voltage applying circuit 5 is also a circuit to select some unselected bit lines which are not selected in the bit line selection circuit 3 from the local bit lines LBL1 to 5 during the reading operation and apply a predetermined drain voltage to be supplied from the drain voltage supply line VDB to the selected unselected bit line via the corresponding global bit lines GBL1 to 5.

Hereinafter, the memory operation such as the writing operation, the erasing operation, and the reading operation for the memory cell will be specifically described below.

At first, the writing action will be described. The writing action is carried out by injecting an electric charge in the floating gate of the memory cell to be written by means of injection of a channel hot electron (CHEI) and raising a threshold voltage of the memory cell transistor. As an example, the written action into the memory cell MA in FIG. 1 will be specifically described.

Making the block selection signal SEL into a high level, the global bit lines GBL1 to 5 are connected to the local bit lines LBL1 to 5, respectively. Then, making the ground control signal PDN2 into a high level, the local bit line LBL2 is connected to ground via the global bit line GBL2; making the drain voltage control signal CB1 into a high level, the local bit line LBL1 is connected to the drain voltage supply line VDB via the global bit line GBL1; and the writing drain voltage to be supplied from the drain voltage supply line VDB is applied to the local bit line LBL1. Applying the writing gate voltage to the word line WL 2, writing to the memory cell MA will be done.

The erasing operation is carried out in blocks due to a FN (Fowler Nordheim) tunnel effect. For example, applying a negative voltage to the all word lines of the blocks to be erased and applying a positive high voltage to a back gate well of the memory cell, the all memory cells in the block are collectively erased.

The reading operation and the verify operation (the reading operation for verification of writing or erasing) are carried out by applying the reading voltage to the drain with the source of the selected memory cell to be read being connected to ground and applying the reading gate voltage to the word line. Hereinafter, defining the memory cell MA in FIG. 1 as the selected memory cell, the reading operation will be specifically described.

Making the block selection signal SEL into a high level, the global bit lines GBL1 to 5 are connected to the local bit lines LBL1 to 5. Making the ground control signal PDN1 into a high level, the local bit line LBL1 (equivalent to a selected source line) to be connected to the source region of the selected memory cell MA is connected to ground via the global bit line GBL1, and making the bit line selection signals YS2 and YS3 into high levels, the local bit lines LBL2 and LBL3 are connected to the input end CMN of the reading circuit 4 via the global bit lines GBL2 and GBL3. Here, a reading drain voltage (for example 1V) to be supplied from the current-voltage converting circuit 6 to the input end CMN is applied to each of the local bit lines LBL2 and LBL3. Making a drain voltage control signal CB4 into a high level, the local bit line LBL4 is connected to the drain voltage supply wire VDB via the global bit line GBL4 so as to apply the drain voltage to be supplied to the drain voltage supply wire VDB to the local bit line LBL4. In this time, it is preferable that the voltage of the drain voltage supply wire VDB is the same as the reading drain voltage V_{CMN} (the voltage of the input end CMN in FIG. 1). Applying the reading gate voltage (for example, 4V) to the word line WL2, the selected memory cell MA is read.

Here, the local bit line LBL2 is the selected bit line to be connected to the drain region of the selected memory cell MA, and the local bit line LBL3 is equivalent to one piece of the additional bit line group made of one and more arbitrary local bit lines located at the opposite side of the selected source line LBL1 with respect to the selected bit line LBL2, selected from the local bit lines LBL1 to 5 except the selected bit line LBL2. In addition, the local bit line LBL4 is equivalent to an outside bit line located at the outside from the additional bit line group LBL3 as seen from the selected bit line LBL2.

While maintaining the reading drain voltage V_{CMN} at the input end CMN at a constant voltage, the voltage converting circuit 6 lowers the reading voltage V_{READ} at the output end MN to be connected to one input end of the sense amplifier 7 when the threshold voltage of the selected memory cell MA is low and the reading current Icell is large, and when the threshold voltage of the selected memory cell MA is high and the reading current Icell is small, the voltage converting circuit 6 raises the reading voltage V_{READ}. The sense amplifier 7 reads the data of the selected memory cell MA by comparison-amplifying the reading voltage V_{READ} with the reference voltage V_{REF}.

During the reading operation, in the drain voltage of the selected memory cell MA (the voltage at a (B) point in FIG. 1), a voltage drop ΔV shown in the following mathematical expression 2 lowers from the reading drain voltage V_{CMN} due to an influence of a synthetic resistance Rt of the on-resistance of the MOSFET and the wire resistance on the global bit line GBL2 and the local bit line LBL2.
ΔV=Icell×Rt (Mathematical Expression 2)

Due to this voltage drop ΔV, a potential difference is generated between the (B) point on the local bit line LBL2 and the (C) point on the local bit line LBL3, and a leak current to be changed depending on the threshold voltage of the adjacent memory cell MB is generated via the adjacent memory cell MB, which is adjacent to the drain side of the selected memory cell MA, namely, which is located between the (B) point and the (C) point. However, according to the circuit constitution of the present embodiment, by connecting the local bit line LBL3 to the input end CMN of the reading circuit 4 by means of the bit line selection circuit 3, the leak current from the adjacent memory cell MB can be used as the reading current, so that it is possible to transfer the all reading currents Icell flowing through the selected memory cell MA to the side of the reading circuit 4.

Here, the local bit line LBL3 is directly supplied with a voltage from the input end CMN and the voltage is decided independently from the local bit line LBL2, so that the voltage at the (C) point on the local bit line LBL3 drops by the minute leak current unlike the voltage at the (B) point on the local bit line LBL2. Further, this leak current is changed depending on the threshold voltage of the adjacent memory cell MB; however, even in a case where the threshold voltage is low, since the potential difference between the drain and the source is smaller than the selected memory cell MA, this leak current is about 1/10 of the reading current Icell of the selected memory cell MA. As a result, the voltage at the (C) point is nearly the same as the reading drain voltage V_{CMN} of the input end CMN, and the voltage at the (D) point on the local bit line LBL4 to be connected to the drain voltage supply wire VDB to supply the same voltage as the reading drain voltage V_{CMN} becomes nearly the same as the voltage at the (C) point. In other words, the potential difference between the drain and the source of the memory cell sandwiched between the local bit lines LBL3 and LBL4 becomes nearly 0V, so that no leak current flows between the local bit line LBL3 and the local bit line LBL4. As a result, the reading current Iread flowing through the current-voltage converting circuit 6 via the input end CMN is equal to the reading cell current Icell independently of the leak current to be changed by the threshold voltage of the adjacent memory cells MB and MC adjacent to the drain side of the selected memory cell MA.

Next, another embodiment of the device according to the present invention will be described.

(1) According to this embodiment, a case of maintaining during the reading operation the state that the drain voltage control signal CB4 is made into a high level in the reading operation to connect the local bit line LBL4 to the drain voltage supply line VDB via the global bit line GBL4 and apply the drain voltage to be supplied to the drain voltage supply line VDB to the local bit line LBL4 is described; however, making the drain voltage control signal CB4 into a low level, the local bit line LBL4 may be made into a floating state after sufficiently pre-charging the local bit line LBL4 to this drain voltage.

(2) According to the present embodiment, a case where the drain voltage control signal CB4 is made into a high level during the reading operation to connect the local bit line LBL4 to the drain voltage supply line VDB via the global bit line GBL4 and apply this drain voltage to be supplied to the drain voltage supply line VDB to the local bit line LBL4 is described; however, the outside bit line to apply this drain voltage during the reading operation may not be limited to the local bit line LBL4 but may be a local bit line LBL5 or the like at the further outside of the local bit line LBL4. Then, the drain voltage control signals CB4 and CB5 are made into high levels at the same time. In this case, the voltage applied state of the local bit line LBL5 may be maintained during the reading operation or the drain voltage control signal CB5 may be made into a low level and into a floating state after sufficiently pre-charging the voltage of the local bit line LBL5 to this drain voltage.

(3) According to the above-described embodiment, a case where the bit line control signals YS2 and YS3 are made into high levels during the reading operation to connect the local bit lines LBL2 and LBL3 to the input end CMN of the reading circuit 4 via the global bit lines GBL2 and GBL3 is described; however, as the additional bit line group, the local bit line to be connected to the input end CMN of the reading circuit 4 other than the selected bit line LBL2 is not limited to the local bit line LBL3.

For example, making the block selection signal SEL into a high level, the global bit lines GBL1 to 5 are connected to the local bit lines LBL1 to 5; making the ground control signal PDN1 into a high level, the local bit line LBL1 (equivalent to the selected source line) to be connected to the source region of the selected memory cell MA is connected ground via the global bit line GBL1; and making the bit line selection signals YS2 and YS4 into high levels, the local bit lines LBL2 and LBL4 are connected to the input end CMN of the reading circuit 4 via the global bit lines GBL2 and GBL4. Here, the reading drain voltage (for example, 1V) to be supplied from the current-voltage converting circuit 6 to the input end CMN is applied to each of the local bit lines LBL2 and LBL4. Making the drain voltage control signals CB3 and CB5 into high levels, the local bit lines LBL3 and LBL5 are connected to the drain voltage supply line VDB, respectively, via the global bit lines GBL3 and GBL5, and the drain voltage to be supplied to the drain voltage supply line VDB is applied to the local bit lines LBL3 and LBL5, respectively. In this time, it is preferable that the voltage of the drain voltage supply line VDB is the same as the reading drain voltage V_{CMN} (the voltage of the input end CMN in FIG. 1). Sufficiently pre-charging the voltage of the local bit line LBL3 (equivalent to the adjacent bit line) to the drain voltage to be supplied from the drain voltage supply line VDB, and then, making a drain voltage control signal CB3 into a low level, the state of the local bit line LBL3 may be made into the floating state as being pre-charged. Then, applying the reading gate voltage (for example 4V) to the word line WL 2, the selected memory cell MA will be read.

During the reading operation, in the drain voltage of the selected memory cell MA (the voltage at the (B) point in FIG. 1), the voltage drop ΔV shown in the mathematical expression 2 lowers from the reading drain voltage V_{CMN} due to an influence of a synthetic resistance Rt of the on-resistance of the MOSFET and the wire resistance on the global bit line GBL2 and the local bit line LBL2.

Due to this voltage drop ΔV, a potential difference is generated between the (B) point on the local bit line LBL2 and the (D) point on the local bit line LBL4, and a leak current changing depending on the threshold voltage of the adjacent memory cells MB and MC is generated via the adjacent memory cells MB and MC, which are adjacent to the drain side of the selected memory cell MA, namely, which is located between the (B) point and the (D) point. However, according to the circuit constitution of the present embodiment, by connecting the local bit line LBL4 to the input end CMN of the reading circuit 4 by means of the bit line selection circuit 3, the leak current from the adjacent memory cells MB and MC can be used as the reading current, so that it is possible to transfer the all reading currents Icell flowing through the selected memory cell MA to the side of the reading circuit 4.

In addition, according to the present other embodiment (3), by setting the local bit line LBL3 between the selected bit line and the additional bit line group as one or more adjacent bit lines to be a floating state, the potential difference between the drain and the source of two memory cells MB and MC located between the local bit lines LBL2 and LBL4 to be connected to the input end CMN of two reading circuits 4 is divided by the adjacent bit line LBL3. Therefore, for example, in a case where there is one adjacent bit line, the potential difference is made into half of a case where no adjacent line in the floating state is set between the selected bit line and the additional bit line group.

(4) According to the above-described other embodiment (3), there is only one local bit line LBL3 as the adjacent bit line being the floating state between the selected bit line LBL2 and the additional bit line group LBL4 connected to the input end CMN of the reading circuit 4; however, there may be two or more adjacent bit lines being in the floating state.

(5) According to the above-described other embodiment (3), a case of maintaining during the reading operation the state that the drain voltage control signal CB5 is made into a high level to connect the local bit line LBL5 to the drain voltage supply line VDB via the global bit line GBL5 and apply the drain voltage to be supplied to the drain voltage supply line VDB to the local bit line LBL5 is described; however, making the drain voltage control signal CB5 into a low level, the local bit line LBL5 may be made into a floating state after sufficiently pre-charging the local bit line LBL5 to this drain voltage.

In addition, the outside bit line to which this drain voltage is applied during the reading operation is not limited to the local bit line LBL5 but it may be a local bit line at the further outside of the local bit line LBL5 (not illustrated). In this case, the voltage applying state of this outside local bit line may be maintained during the reading operation, or this outside local bit line may be into a floating level making the drain voltage control signal into a low level after sufficiently pre-charging the outside local bit line to this drain voltage.

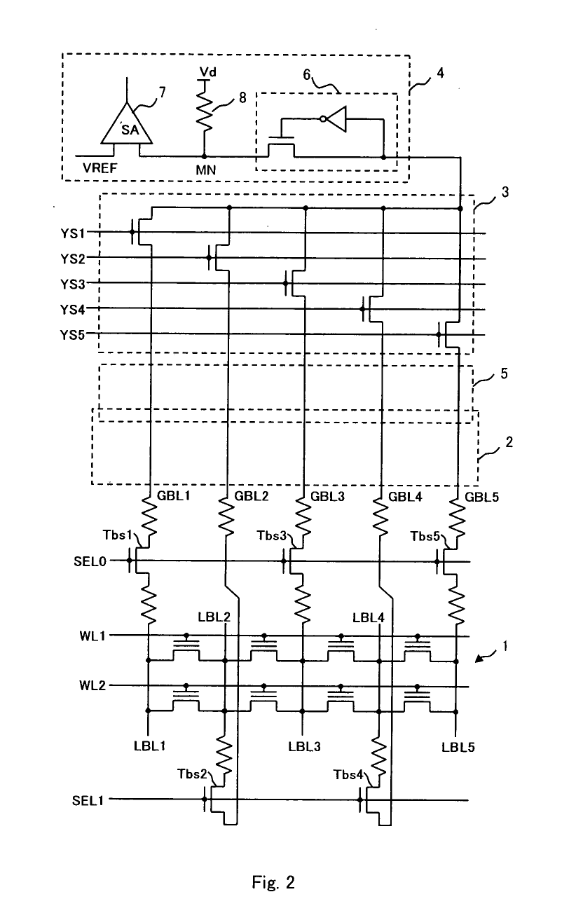

(6) According to the above-described embodiment and respective other embodiments, as shown in FIG. 1, a case where the block selection transistors Tbs1 to 5 are provided at one ends of the local bit lines LBL1 to 5 of each block is illustrated; however, as shown in FIG. 2, the connected positions of the block selection transistors Tbs1 to 5 are different in the odd-numbered local bit lines LBL1, 3, and 5 and the even-numbered local bit lines LBL2 and 4. For example, it is also a preferable embodiment such that the block selection transistors Tbs1, 3, and 5 are connected to the upper ends of the local bit lines LBL1, 3, and 5; the block selection transistors Tbs2, 4 are connected to the lower ends of the local bit lines LBL2 and 4, respectively; and they are independently controlled to be turned on and off.

(7) According to the above-described embodiment and respective other embodiments, as shown in FIG. 1 and FIG. 2, the constitution such that the memory cell array 1 is divided into a plurality of blocks in a row direction; and the local bit lines LBL1 to 5 of respective blocks are separately connected to the global bit lines GBL1 to 5 via the block selection transistors Tbs1 to 5 having the block selection signal SEL as a gate signal is described as an example; however, the memory cell array 1 may not always be divided into a plurality of blocks in a row direction. In this case, the circuit constitution is given such that respective local bit lines LBL1 to 5 are directly connected to the ground voltage applying circuit 2, the bit line selection circuit 3, and the drain voltage applying circuit 5 not via the global bit lines GBL1 to 5.

The nonvolatile semiconductor memory device of the virtual ground type according to the present invention is available for the nonvolatile semiconductor memory device provided with the memory cell array of the virtual ground type.

Although the present invention has been described in terms of the preferred embodiment, it will be appreciated that various modifications and alternations might be made by those skilled in the art without departing from the spirit and scope of the invention. The invention should therefore be measured in terms of the claims which follow.

What is claimed is:

1. A virtual ground type nonvolatile semiconductor memory device including a virtual ground type memory cell array consisting of a plurality of memory cells, each having a MOSFET construction, arranged in a matrix in a row direction and a column direction, wherein gates of the memory cells in the same row are connected to a common word line extending in the row direction, drain regions and source regions of the memory cells in the same column are separately connected to two bit lines, each extending in the column direction, and a drain region or a source region of one of the two memory cells adjacent in the row direction and a drain region or a source region of the other of the two memory cells are connected with each other to share the bit line, the virtual ground type nonvolatile semiconductor memory device comprising
a ground voltage applying circuit for applying a ground voltage to a selected source line which is the bit line connected to a source region of a selected memory cell to be read of the memory cells during a reading operation;
a reading circuit for supplying a reading current to the selected memory cell via a selected bit line which is the bit line connected to a drain region of the selected memory cell during a reading operation and detecting stored data of the selected memory cell based on the reading current; and
a bit line selection circuit for selecting the selected bit line from the bit lines and connecting the selected bit line to the reading circuit, wherein
the bit line selection circuit can select an additional bit line group made of one or more arbitrary bit lines located at an opposite side of the selected source line with respect to the selected bit line from the bit lines, and connect the additional bit line group to the reading circuit and
a current path from an input end of the reading circuit branches into current paths to the selected bit line and respective bit lines of the additional bit line group at a side of the reading circuit from the bit line selection circuit.

2. The virtual ground type nonvolatile semiconductor memory device according to claim 1, wherein
the bit line selection circuit makes adjacent bit lines which are one or more arbitrary bit lines located at an opposite side of the selected source line with respect to the selected bit line to be unselected and into a floating state.

3. The virtual ground type nonvolatile semiconductor memory device according to claim 2, wherein
the adjacent bit line to be made into the floating state by the bit line selection circuit is charged to a predetermined pre-charged voltage before being made into the floating state.

4. The virtual ground type nonvolatile semiconductor memory device according to claim 3, wherein
the adjacent bit line to be made into the floating state by the bit line selection circuit is charged to a pre-charged voltage which is the same as a voltage of the selected bit line before being made into the floating state.

5. The virtual ground type nonvolatile semiconductor memory device according to claim 1, wherein
when another bit line exists at an outside from the additional bit line group as seen from the selected bit line, the bit line selection circuit makes an outside bit line located at the outside to be unselected and into a floating state.

6. The virtual ground type nonvolatile semiconductor memory device according to claim 5, wherein
the outside bit line to be made into the floating state by the bit line selection circuit is charged to a predetermined pre-charged voltage before being made into the floating state.

7. The virtual ground type nonvolatile semiconductor memory device according to claim 6, wherein
the outside bit line to be made into the floating state by the bit line selection circuit is charged to a pre-charged voltage which is the same as a voltage of the selected bit line before being made into the floating state.

8. The virtual ground type nonvolatile semiconductor memory device according to claim 1, wherein
when another bit line exists at an outside from the additional bit line group as seen from the selected bit line, a predetermined bias voltage is applied to an outside bit line located at the outside.

9. The virtual ground type nonvolatile semiconductor memory device according to claim 8, wherein
the bias voltage to be applied to the outside bit line is the same as a voltage of the selected bit line.

10. The virtual ground type nonvolatile semiconductor memory device according to claim 1, wherein
the reading circuit comprises a current-voltage converting circuit for converting a change in the reading current flowing through the selected memory cell via the selected bit line into a change in voltage and outputting the change in voltage as a reading voltage while suppressing a voltage variation on the selected bit line, and a sense amplifier for amplifying the reading voltage to be outputted from the current-voltage converting circuit.

11. The virtual ground type nonvolatile semiconductor memory device according to claim 1, wherein
the memory cell array is divided into a plurality of blocks in a column direction;
the bit line extending in the column direction is divided in blocks;
each bit line in the block is connected to a main bit line corresponding to the bit line one-on-one via a block selection transistor;
the block including the selected memory cell is selected by the block selection transistor; and
the bit line selection circuit selects the main bit line to be connected independently to the selected bit line and each bit line of the additional bit line group via the block selection transistor when selecting the selected bit line and the additional bit line group from the bit lines.

12. The virtual ground type nonvolatile semiconductor memory device according to claim 11, wherein
a source electrode of the block selection transistor which is provided on each bit line for each block is independently connected to any one side of the both ends of each bit line;
connecting positions of the block selection transistors are different between odd-numbered bit lines and even-numbered bit lines; and
the block selection transistor to be connected to the odd-numbered bit line and the block selection transistor to be connected to the even-numbered bit line are independently controlled to be turned on and off.
